(19) United States
(12) Patent Application Publication
(10) Pub. No.: US 2026/0126745 A1
(43) Pub. Date: May 7, 2026

(54) MEDIA DETECTION APPARATUS, IMAGE FORMING SYSTEM, AND RECORDING MEDIUM

(71) Applicant: Konica Minolta, Inc., Tokyo (JP)

(72) Inventors: Hitoshi Asano, Toyokawa-shi (JP); Kenji Izumiya, Tokyo (JP); Hiroshi Oyama, Tokyo (JP); Akira Okamoto, Tokyo (JP); Masayuki Watanabe, Tokyo (JP); Shota Igo, Tokyo (JP); Hiroshi Yamaguchi, Tokyo (JP)

(73) Assignee: Konica Minolta, Inc., Tokyo (JP)

(21) Appl. No.: 19/380,316

(22) Filed: Nov. 5, 2025

(30) Foreign Application Priority Data
Nov. 6, 2024 (JP) 2024-194136

(51) Int. Cl. G03G 15/00; H01S 5/024

(52) U.S. Cl. CPC G03G 15/5029; H01S 5/02415; G03G 2215/00776; G03G 2215/0404

(57) ABSTRACT

A media detection apparatus for detecting moisture information corresponding to a moisture amount or a moisture percentage of a sheet, the media detection apparatus including: a moisture sensor including a light emitter that emits light and a light receiver that receives the light reflected off the sheet or transmitted through the sheet; and a hardware processor that controls a temperature of the light emitter such that a wavelength of the light emitted from the light emitter becomes a predetermined wavelength.

### CROSS-REFERENCE TO RELATED APPLICATIONS

The entire disclosure of Japanese Patent Application No. 2024-194136 filed on Nov. 6, 2024 is incorporated herein by reference in its entirety.

### BACKGROUND OF THE INVENTION

### Technical Field

The present disclosure relates to a media detection apparatus, an image forming system, and a recording medium.

### Description of Related Art

In a conventionally known image forming apparatus, a media sensor is installed partway along a conveyance path of a sheet, and characteristic values of a sheet transported along the conveyance path are detected by the media sensor. Next, the image forming apparatus determines image formation condition in accordance with the characteristic value of the sheet detected by the media sensor, and forms an image on the sheet.

When the moisture percentage of a sheet is measured using a moisture sensor as a media sensor, the measurement result may change although the sheet is in the same state. This is because the moisture sensitivity changes as the wavelength of the light emitted by the light emitting section changes due to a change in the temperature of the light emitting section caused by a temperature increase or the like due to self-heating of the light emitting section (LED or the like) itself included in the moisture sensor. Due to such a phenomenon, there is a problem that an error occurs in the moisture percentage of the sheet detected by the moisture sensor with respect to the original moisture percentage of the sheet.

For example, Japanese Unexamined Patent Publication No. 2024-115578 describes that, for the above-described phenomenon, the moisture percentage of the sheet detected by the moisture sensor is corrected based on the temperature of the light emitting section and correction values set in advance for respective representative paper types such as plain paper and thick paper.

### SUMMARY OF THE INVENTION

However, the change characteristics of the light absorptivity due to the moisture in the sheet differ depending on the composition, sheet thickness, color, surface shape, and the like of the sheet. Therefore, in a case where the moisture percentage of the sheet detected by the moisture sensor is corrected based on the correction value corresponding to the representative paper type as in the invention described in Japanese Unexamined Patent Publication No. 2024-115578, there is a problem that it is difficult to perform sufficient correction for all the paper types.

An object of the present disclosure is to provide a media detection apparatus, an image forming system, and a recording medium that can more accurately detect moisture information corresponding to the moisture amount or the moisture percentage of a sheet.

To achieve at least one of the abovementioned objects, according to an aspect of the present invention, a media detection apparatus reflecting one aspect of the present invention is
a media detection apparatus for detecting moisture information corresponding to a moisture amount or a moisture percentage of a sheet, the media detection apparatus comprising:
a moisture sensor including a light emitter that emits light and a light receiver that receives the light reflected off the sheet or transmitted through the sheet; and
a hardware processor that controls a temperature of the light emitter such that a wavelength of the light emitted from the light emitter becomes a predetermined wavelength.

### BRIEF DESCRIPTION OF THE DRAWINGS

The advantages and features provided by one or more embodiments of the invention will become more fully understood from the detailed description given hereinbelow and the appended drawings which are given by way of illustration only, and thus are not intended as a definition of the limits of the present invention, wherein:

FIG. 1 is a diagram illustrating a schematic configuration of an image forming system according to the present embodiment;

FIG. 2 is a block diagram illustrating a main functional configuration of the image forming system according to the present embodiment;

FIG. 3 is a diagram illustrating a schematic configuration of a moisture sensor;

FIG. 4 is a diagram illustrating an example of the arrangement of the moisture sensor and the heating section;

FIG. 5 is a diagram illustrating an example of the arrangement of the moisture sensor and the heating section;

FIG. 6 is a diagram illustrating an example of the arrangement of the moisture sensor and the heating section;

FIG. 7 is a diagram illustrating an example of temperature characteristic information;

FIG. 8 is a flowchart showing a flow of a temperature control processing executed by the image forming system; and

FIG. 9 is a flowchart illustrating the flow of temperature control processing of a modification example.

### DETAILED DESCRIPTION

Hereinafter, one or more embodiments of the present invention will be described with reference to the drawings. However, the scope of the invention is not limited to the disclosed embodiments.

Embodiments of an image forming system of the present disclosure will be described below with reference to the accompanying drawings. In an embodiment of the present disclosure, an image forming apparatus included in an image forming system will be described taking a system color image forming apparatus as an example. However, the present disclosure is not limited thereto and is also applicable to, for example, a monochrome image forming apparatus.

### 1. Configuration of Image Forming System

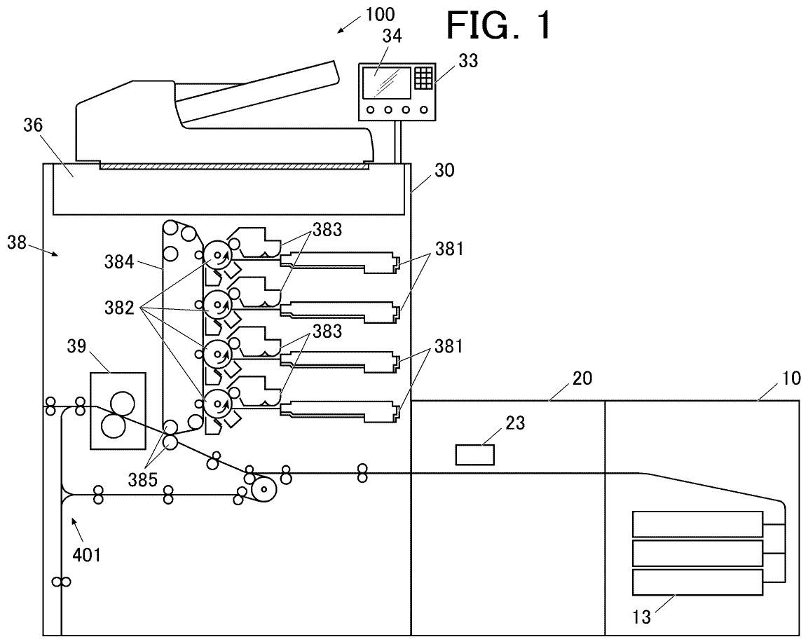

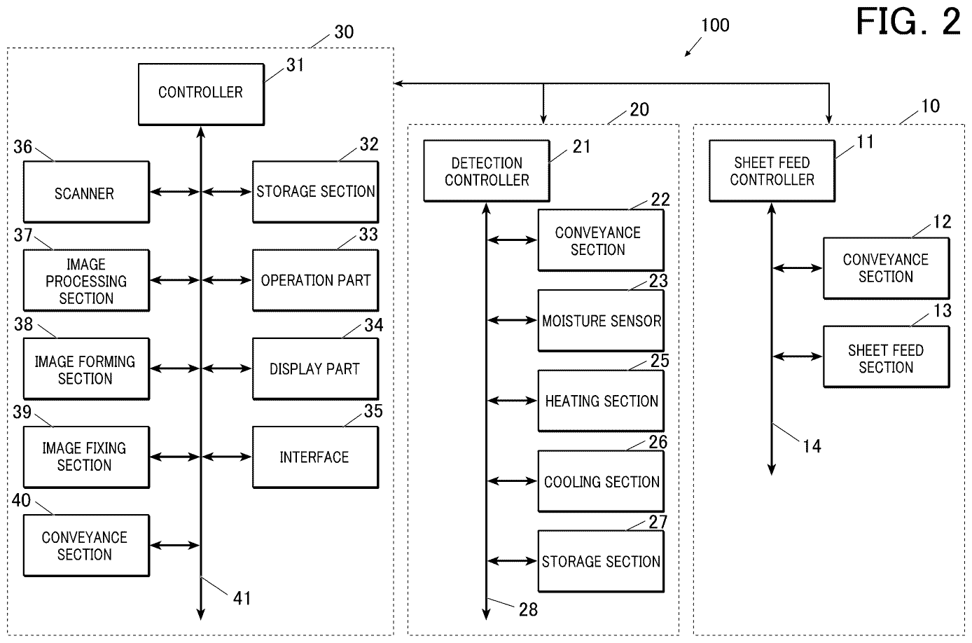

FIG. 1 is a diagram illustrating a schematic configuration of an image forming system 100 according to the present embodiment. FIG. 2 is a block diagram illustrating a main functional configuration of the image forming system 100.

The image forming system 100 according to the present embodiment includes a sheet feed device 10, a media detection apparatus 20 which is a media detection apparatus, and an image forming apparatus 30.

In the image forming system 100, the sheet feed device 10, the detection apparatus 20, and the image forming apparatus 30 are arranged in this order from the upstream along a conveyance direction of the sheet.

### (1-1. Configuration of Sheet Feed Device)

The sheet feed device 10 includes a sheet feed controller 11, a conveyance section 12, sheet feed section 13, and the like.

The sheet feed controller 11 is connected to the conveyance section 12 and the sheet feed section 13 via the bus 14.

The sheet feed controller 11 includes a central processing unit (CPU), a read only memory (ROM), and a random access memory (RAM).

The CPU of the sheet feed controller 11 reads a program stored in the ROM, loads the program into the RAM, and centrally controls each component of the sheet feed device 10 in accordance with the loaded program.

For example, the sheet feed controller 11 conveys a sheet from a sheet feed tray of any one of the sheet feed sections 13 to the detection apparatus 20 according to a job.

The conveyance section 12 conveys the sheet via a conveyance route connecting the sheet feed section 13 to the detection apparatus 20.

The sheet feed section 13 includes a sheet feed tray that stores sheets for each predetermined paper type, size, and the like.

### (1-2. Configuration of Detection Apparatus)

The detection apparatus 20 is provided on an upstream side of the image forming apparatus 30 in the sheet conveyance direction and detects a sheet conveyed from the sheet feed device 10.

The detection apparatus 20 includes a detection controller 21 (hardware processor), a conveyance section 22, a moisture sensor 23, a heating section 25 (heater), a cooling section 26 (cooler), and a storage section 27.

The detection controller 21 is connected to the conveyance section 22, the moisture sensor 23, the heating section 25, the cooling section 26, and the storage section 27 via the bus 28.

The detection apparatus 20 may include at least one of the heating section 25 and the cooling section 26.

The detection controller 21 includes a CPU, ROM, and RAM.

The CPU of the detection controller 21 reads a program stored in the ROM, loads the program into the RAM, and centrally controls each component of the detection apparatus 20 in accordance with the loaded program. For example, the detection controller 21 causes the moisture sensor 23 to detect a sheet conveyed from the sheet feed device 10. Next, the detection controller 21 causes the conveyance section 22 to convey the detected sheet to the image forming apparatus 30.

The conveyance section 22 is formed with a plurality of roller pairs and conveys the sheet conveyed from the sheet feed device 10 to the moisture sensor 23. Next, the conveyance section 22 conveys the sheet detected by the moisture sensor 23 to the image forming apparatus 30.

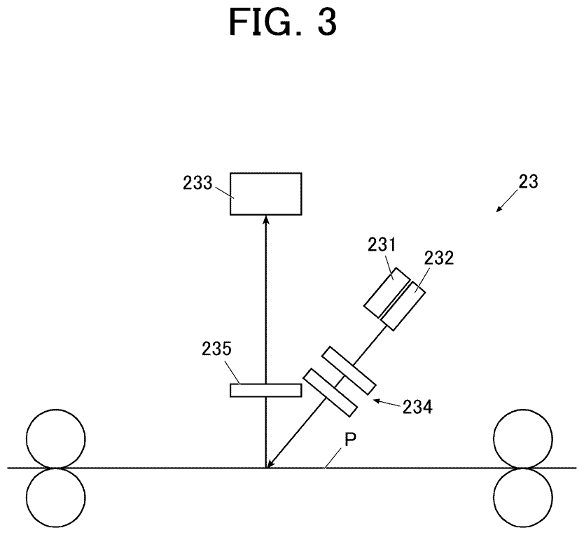

FIG. 3 is a schematic diagram illustrating the configuration of the moisture sensor 23.

As illustrated in FIG. 3, the moisture sensor 23 includes a first light emitting section 231, a second light emitting section 232, a light receiving section 233 (light receiver), lenses 234 and 235, and the like.

The first light emitting section 231 and the second light emitting section 232 are light emitting sections that emit light toward a sheet.

First light emitting section 231 includes a light emitting diode (LED) element or a laser diode element as a light emitting element.

The first light emitting section 231 emits first near-infrared light (reference light) in a specific wavelength band toward a sheet P. The wavelength of the first near-infrared light is, for example, 1300 nm.

The first near-infrared light is light for which the absorptance at the sheet P when the light is reflected off the sheet P does not depend on the moisture percentage of the sheet P.

The light receiving section 233 receives, via the lens 235, the first near-infrared light that has been emitted from the first light emitting section 231, passed through the lens 234, and reflected off the sheet P. Next, the light receiving section 233 outputs information on a first light reception amount that is a light reception amount of the reflected first near-infrared light to the detection controller 21. Specific examples of the light receiving section 233 include a photo diode (PD), a charge-coupled device (CCD), and a complementary metal-oxide-semiconductor (CMOS) image sensor.

Second light emitting section 232 includes, as a light emitting element, an LED element or a laser diode.

The second light emitting section 232 emits second near-infrared light in a specific wavelength range toward the sheet P. The wavelength of the second near-infrared light is, for example, 1450 nm.

The second near-infrared light is light for which the absorptance at the sheet P when the light is reflected off the sheet P varies depending on the moisture percentage of the sheet P.

The light receiving section 233 receives, via the lens 235, the second near-infrared light emitted from the second light emitting section 232 and reflected by the sheet P via the lens 234. Next, the light receiving section 233 outputs information on a second light reception amount that is a light reception amount of the reflected second near-infrared light to the detection controller 21.

That is, the first light emitting section 231 and the second light emitting section 232 emit light having wavelengths with different absorptance by moisture in the sheet.

The second near-infrared light emitted by second light emitting section 232 is light having a wavelength that is absorbed by moisture in the sheet to a greater extent than the first near-infrared light (reference light) emitted by first light emitting section 231.

The detection controller 21 determines the moisture percentage of the sheet on the basis of the ratio of the first light reception amount and the second light reception amount. The ratio of the first light reception amount and the second light reception amount is the ratio of the output of the light receiving section 233 with respect to the first near-infrared light and the second near-infrared light.

Since the moisture percentage of the sheet increases, the amount of the second near-infrared light absorbed increases, and the second light reception amount decreases. Therefore, based on a relational expression, a table, or the like indicating a relationship between the moisture percentage of the sheet and the ratio between the first light reception amount and the second light reception amount, the ratio between the first light reception amount and the second light reception amount can be associated with the moisture percentage of the sheet, and the moisture percentage of the sheet can be calculated from the ratio between the first light reception amount and the second light reception amount.

The detection controller 21 may determine the moisture amount of the sheet based on a ratio of the first light reception amount to the second light reception amount.

The detection controller 21 may determine an index indicating the moisture amount or the moisture percentage of the sheet based on the ratio of the first light reception amount to the second light reception amount.

The moisture information corresponding to the moisture amount or the moisture percentage of the sheet includes the moisture amount of the sheet, the moisture percentage of the sheet, and an index indicating the moisture amount or the moisture percentage of the sheet.

The heating section 25 includes a heat source resistance element 251 disposed in the vicinity of the light emitting section (light emitter), and heats the light emitting section by passing a current through the heat source resistance element 251 (resistor).

The cooling section 26 includes at least one of a fan motor and a Peltier element, and cools the light emitting section by at least one of the fan motor and the Peltier element.

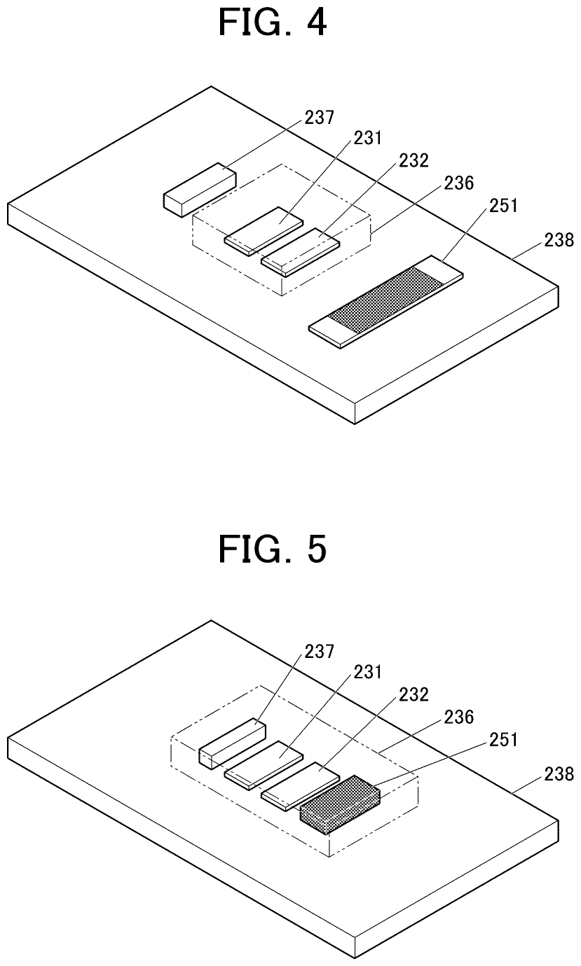

FIG. 4 shows an example of the arrangement of the members constituting the moisture sensor 23 and the heat source resistance element 251.

The moisture sensor 23 includes an LED case 236 that houses the first light emitting section 231 and the second light emitting section 232.

The LED case 236 is placed on the printed circuit board 238.

It is preferable to adopt, as the printed circuit board 238, a metal substrate excellent in heat conduction, but a general glass epoxy substrate using heat conduction of a copper pattern may be adopted.

The moisture sensor 23 includes a temperature sensor 237, such as a thermistor, mounted on the printed circuit board 238 in the vicinity of the first light emitting section 231 and the second light emitting section 232.

Temperature sensor 237 detects the temperature in the vicinity of first light emitting section 231 and second light emitting section 232, and outputs the detection result to detection controller 21.

The heat source resistance element 251 is mounted on the printed circuit board 238 in the vicinity of the first light emitting section 231 and the second light emitting section 232 and on the side opposite to the temperature sensor 237 with the LED case 236 interposed therebetween.

At least one of the fan motor and the Peltier element included in the cooling section 26 is provided on a surface of the printed board 238 opposite to the surface on which the LED case 236 is placed.

FIG. 5 shows another example of the arrangement of the members constituting the moisture sensor 23 and the heat source resistance element 251.

In the example illustrated in FIG. 5, first light emitting section 231, second light emitting section 232, temperature sensor 237, and heat source resistance element 251 are housed in LED case 236 placed on printed circuit board 238. The heat source resistance element 251 is disposed opposite to the temperature sensor 237 across the first light emitting section 231 and the second light emitting section 232.

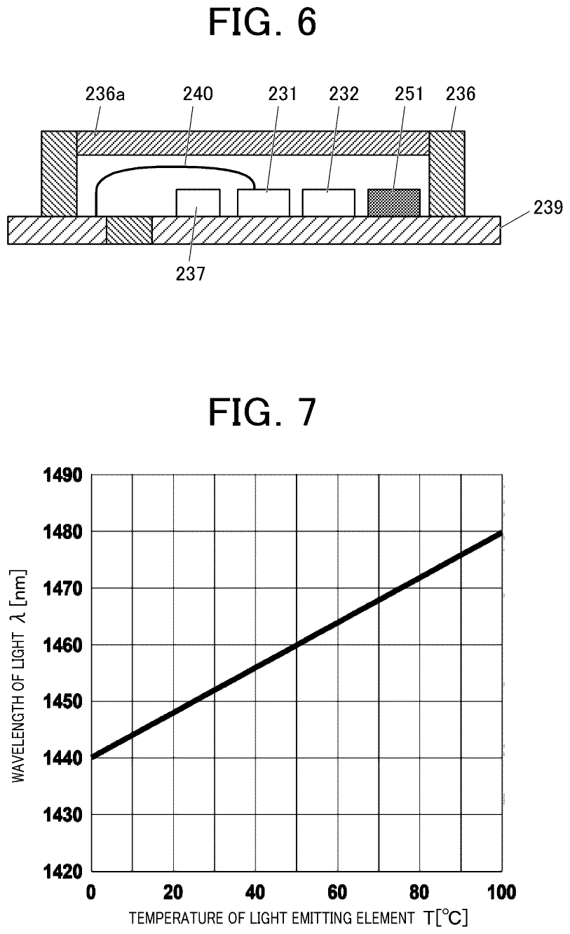

As illustrated in FIG. 6, the first light emitting section 231, the second light emitting section 232, the temperature sensor 237, and the heat source resistance element 251 may be mounted on the soldering terminals 239 for heat sink in order to improve heat conduction among the first light emitting section 231, the second light emitting section 232, the temperature sensor 237, and the heat source resistance element 251.

The LED case 236 includes a window 236a, and light emission from the first light emitting section 231 and the second light emitting section 232 passes through the window 236a and is applied to the sheet.

First light emitting section 231 may be connected to soldering terminal 239 for a heat sink with bonding wire 240.

The storage section 27 is a storage device such as a dynamic random access memory (DRAM), which is a semiconductor memory, or a hard disk drive (HDD).

The storage section 27 stores temperature characteristic information used in temperature control processing to be described later.

FIG. 7 shows an example of the temperature characteristic information.

The temperature characteristic information indicates, for each light emitting element of the second light emitting section 232, a correspondence relationship between the wavelength λ of the second near-infrared light emitted by the second light emitting section 232 and a temperature T of the light emitting element of the second light emitting section 232.

The temperature characteristic information may be a relational expression that indicates, for each light emitting element of the second light emitting section 232, a correspondence relationship between the wavelength of the second near-infrared light emitted by the second light emitting section 232 and the temperature of the light emitting element of the second light emitting section 232.

### 1-3. Configuration of Image Forming Apparatus

The image forming apparatus 30 forms a color image by electrophotographic method on the basis of image data obtained by reading an image from a document or image data of a job received from an external device (not illustrated).

The image forming apparatus 30 includes a controller 31, a storage section 32, an operation part 33, a display part 34, an interface 35, a scanner 36, an image processing section 37, an image forming section 38, an image fixing section 39, a conveyance section 40, and the like.

The controller 31 is connected to the storage section 32, the operation part 33, the display part 34, the interface 35, the scanner 36, the image processing section 37, the image forming section 38 (image former), the image fixing section 39, and the conveyance section 40 via a bus 41.

The controller 31 includes a CPU, ROM, and RAM.

The CPU of the controller 31 reads a control program stored in the ROM, loads the program into the RAM, and centrally controls each component of the image forming apparatus 30 in accordance with the loaded program.

For example, the controller 31 causes the image processing section 37 to perform predetermined image processing on image data, and causes the storage section 32 to store the processed image data. Next, the controller 31 causes the conveyance section 40 to convey the sheet, and causes the image forming section 38 to form an image on the sheet on the basis of the image data stored in the storage section 32.

The storage section 32 is a storage device such as a DRAM or an HDD which is a semiconductor memory.

The storage section 32 stores image data acquired by the scanner 36, image data input from the outside via the interface 35, and the like. The RAM included in the controller 31 may store these image data and the like.

The operation part 33 includes operation keys and an input device such as a touch screen arranged to overlap the screen of the display part 34. The operation part 33 converts an input operation on these input devices into an operation signal and outputs the operation signal to the controller 31.

The display part 34 includes a display device such as a liquid crystal display (LCD), and displays a state of the image forming system 100, an operation screen indicating content of an input operation to the touch screen, and the like.

The interface 35 transmits and receives data to and from an external computer, another image forming apparatus, or the like. The interface 35 includes, for example, any of various serial interfaces.

The scanner 36 reads an image formed on a sheet and outputs a reading result to the controller 31. The controller 31 generates image data including single-color image data for each color component of R (red), G (green), and B (blue) based on the reading result by the scanner 36, and stores the image data in the storage section 32.

The image processing section 37 includes, for example, a rasterization processing section, a color conversion section, a gradation correction section, and a halftone processing section. The image processing section 37 performs various kinds of image processing on the image data stored in the storage section 32 and stores the processed image data in the storage section 32.

The image forming section 38 forms an image on a sheet on the basis of image data stored in the storage section 32. The image forming section 38 includes four sets of an exposure section 381, a photosensitive drum 382, a developing section 383, a transfer body 384, a secondary transfer roller 385, and the like corresponding to color components of C (cyan), M (magenta), Y (yellow), and K (black), respectively.

The exposure section 381 includes a laser diode (LD), drives the LD based on image data. The charging photosensitive drum 382 is irradiated and exposure to laser light to form an electrostatic latent image on the photosensitive drum 382. The developing section 383 develops the electrostatic latent image formed on the photosensitive drum 382 by supplying toner (color material) of a predetermined color (any of C, M, Y, and K) onto the exposed photosensitive drum 382 by a charged developing roller.

The images (single-color images) formed with the toners of C, M, Y, and K on the four photosensitive drums 382 corresponding to C, M, Y, and K are sequentially transferred and superimposed onto the transfer body 384 from the photosensitive drums 382. Thus, a color image having the color components of C, M, Y, and K is formed on the transfer member 384. The transfer body 384 is an endless belt wound around a plurality of transfer body conveyance rollers, and rotates in accordance with the rotation of each of the transfer body conveyance rollers.

The secondary transfer roller 385 transfers the color image on the transfer body 384 onto a sheet fed from the sheet feed device 10. Specifically, the sheet and the transfer member 384 are nipped in a transfer nip portion formed by the pair of secondary transfer rollers 385 being in pressure contact with each other. Next, a predetermined transfer voltage is applied to the secondary transfer roller 385, so that the toner forming the color image on the transfer member 384 is attracted to the sheet side and transferred onto the sheet.

The image fixing section 39 includes a fixing roller, a pressure roller, and the like. The image fixing section 39 performs fixing processing of fixing the toner to the sheet by heating and pressing the sheet to which the toner has been transferred.

The conveyance section 40 includes a plurality of sheet conveyance rollers that convey a sheet by rotating while pinching the sheet, and conveys the sheet along a predetermined conveyance route.

The conveyance section 40 includes a reversing mechanism 401 that reverses the front and back of the sheet on which fixing processing has been performed by the image fixing section 39 and conveys the sheet to the secondary transfer roller 385. In the case of forming images on both sides of the sheet, the conveyance section 40 reverses the front and back of the sheet by the reversing mechanism 401 and ejects the sheet after the images are formed on both sides of the sheet. On the other hand, when an image is formed only on one side of the sheet, the conveyance section 40 ejects the sheet having the image formed on one side without reversing the front and back of the sheet by the reversing mechanism 401.

In the present embodiment, the controller 31 of the image forming apparatus 30 integrally controls the entire image forming system 100, but the present invention is not limited thereto. The detection controller 21 of the detection apparatus 20 may be configured to centrally control the entire image forming system 100.

### 2. Operation of Image Forming System

Next, operation by the image forming system 100 will be described.

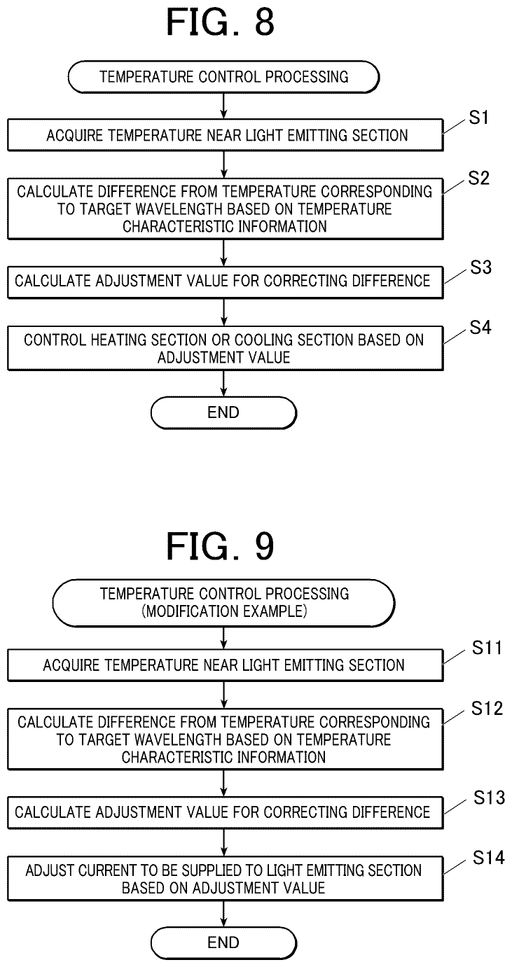

FIG. 8 is a flowchart illustrating a flow of temperature control processing performed by the detection controller 21 while the detection apparatus 20 is detecting moisture information of a sheet by the moisture sensor 23.

The CPU of the detection controller 21 executes temperature control processing in cooperation with a program stored in the ROM.

The light emitted from the first light emitting section 231 has a relatively small change in moisture sensitivity with a change in the wavelength of the light. Therefore, the detection controller 21 executes the temperature control processing to control the temperature of the light emitting section such that the wavelength of the light emitted from the second light emitting section 232 becomes a target wavelength. The detection controller 21 functions as a temperature controller.

### (Temperature Control Processing)

The detection controller 21 acquires the temperature in the vicinity of the light emitting section from the temperature sensor 237 (step S1).

Next, the detection controller 21 calculates, based on the temperature characteristic information stored in the storage section 27, the difference between the temperature in the vicinity of the light emitting section acquired in step S1 and the temperature corresponding to the target wavelength (e.g., 1450 nm) of the light emitted by the second light emitting section 232 (step S2).

Next, the detection controller 21 calculates an adjustment value for the current to be supplied to the heating section 25 or the cooling section 26 in order to correct the difference calculated in step S2 (step S3).

Next, the detection controller 21 controls the heating section 25 or the cooling section 26 based on the adjustment value calculated in step S3 (step S4), and ends the temperature control processing.

In step S4, the detection controller 21 applies an electric current corresponding to the adjustment value to the heat-source resistance elements 251 of the heating section 25 to heat the light emitting section, thereby adjusting the temperature of the light emitting section to a temperature corresponding to the target wavelength of the light emitted by the second light emitting section 232.

Alternatively, the detection controller 21 applies a current corresponding to the adjustment value to at least one of the fan motor and the Peltier element of the cooling section 26 to cool the light emitting section, thereby setting the temperature of the light emitting section to a temperature corresponding to the target wavelength of the light to be emitted by the second light emitting section 232.

### 3. Modification Example

Next, modification example of the present disclosure will be described. In the modification example, components similar to those of the above embodiment are denoted by the same reference numerals, and description thereof will be omitted.

FIG. 9 is a flowchart illustrating a flow of temperature control processing of the present modification example.

The detection controller 21 executes the temperature control processing of the modification example at a timing before the detection apparatus 20 detects the moisture information of the sheet with the moisture sensor 23 and while the detection apparatus 20 does not detect the moisture information of the sheet with the moisture sensor 23.

### (Temperature Control Processing of Modification Example)

The detection controller 21 executes step S11 and step S12 similar to step S1 and step S2 of the temperature control processing of the above-described embodiment.

Next, detection controller 21 calculates an adjustment value for the current to be supplied to the light emitting elements of first light emitting section 231 and second light emitting section 232 for correcting the difference calculated in step S12 (step S13).

Next, based on the adjustment values calculated in step S13, the detection controller 21 adjusts the currents to be supplied to the light emitting elements of the first light emitting section 231 and the second light emitting section 232 (step S14), and ends the temperature control processing of the modification example. Accordingly, the detection controller 21 heats the light emitting section to set the temperature of the light emitting section to a temperature corresponding to the target wavelength of the light emitted by the second light emitting section 232.

In step S14, detection controller 21 may adjust the duty ratio of the current to be supplied to the light emitting elements of first light emitting section 231 and second light emitting section 232, based on the adjustment value calculated in step S13.

Although the present disclosure has been described based on the above embodiments, the description in the above embodiments is an example of the image forming system according to the present disclosure, and the present disclosure is not limited thereto.

For example, when the image forming apparatus 30 includes a sensing section that detects the temperature (environmental temperature) in the image forming apparatus 30, the detection controller 21 may acquire the detection result of the sensing section from the image forming apparatus 30 and control the temperature of the light emitting section while the moisture sensor 23 detects the moisture information of the sheet based on the detection result of the sensing section.

In the above-described embodiment, the light receiving section 233 receives the light emitted from the first light emitting section 231 and the second light emitting section 232 and reflected off the sheet P, but the present invention is not limited thereto. The light receiving section 233 may be configured to receive light that is emitted from the first light emitting section 231 and the second light emitting section 232 and then transmitted through the sheet P.

### 4. Effects

As described above, the media detection apparatus (the detection apparatus 20) according to the present embodiment is a media detection apparatus for detecting moisture information corresponding to the moisture amount or the moisture percentage of the sheet.

The media detection apparatus according to the present embodiment includes the moisture sensor 23 including the light emitting section (second light emitting section 232) that emits light and the light receiving section 233 that receives the light reflected off the sheet or the light transmitted through the sheet.

The media detection apparatus according to the present embodiment includes a temperature controller (detection controller 21) that controls the temperature of the light emitting section so that the wavelength of the light emitted from the light emitting section becomes a predetermined wavelength.

Therefore, since it is possible to suppress a change in moisture sensitivity due to a change in the wavelength of the light emitted by the light emitting section, it is possible to suppress the occurrence of an error in the moisture percentage of the sheet detected by the moisture sensor with respect to the original moisture percentage of the sheet.

Thus, the moisture information corresponding to the moisture amount or the moisture percentage of the sheet can be detected more accurately.

In the media detection apparatus (detection apparatus 20) according to the present embodiment, the temperature controller (detection controller 21) controls the temperature of the light emitting section during the detection of the moisture information based on the measurement result by the temperature sensor 237 disposed in the vicinity of the light emitting section (second light emitting section 232).

Therefore, the temperature of the light emitting section can be appropriately controlled based on the measurement result by the temperature sensor 237 disposed in the vicinity of the light emitting section.

The media detection apparatus (detection apparatus 20) according to the present embodiment includes at least one of the heating section 25 that heats the light emitting section (second light emitting section 232) and the cooling section 26 that cools the light emitting section.

Therefore, by controlling at least one of the heating section 25 and the cooling section 26, the temperature of the light emitting section can be easily controlled.

In the present embodiment, the media detection apparatus (detection apparatus 20), the temperature controller (detection controller 21) heats the light emitting section by passing an electric current through the resistance element (heat source resistance element 251) disposed in the vicinity of the light emitting section (second light emitting section 232) of the heating section 25.

Therefore, the temperature of the light emitting section can be easily controlled by passing an electric current through the heat source resistance element 251.

In the media detection apparatus (detection apparatus 20) according to the present embodiment, the temperature controller (detection controller 21) cools the light emitting section (second light emitting section 232) with at least one of the fan motor and the Peltier element included in the cooling section 26.

Therefore, the temperature of the light emitting section can be easily controlled by at least one of the fan motor and the Peltier element.

In the present embodiment, the media detection apparatus (detection apparatus 20) according to the present embodiment, the light emitting section (second light emitting section 232) includes an LED element or a laser diode element.

Therefore, even in a case where the light emitting section generates heat by itself, it is possible to more accurately detect the moisture information corresponding to the moisture amount or the moisture percentage of the sheet by controlling the temperature of the light emitting section.

In the present embodiment, the media detection apparatus (detection apparatus 20) according to the present embodiment, the temperature controller (detection controller 21) controls the temperature of the light emitting section on the basis of the temperature characteristic information indicating, for each light emitting element of the light emitting section (second light emitting section 232), the correspondence relationship between the wavelength of the light emitted from the second light emitting section 232 and the temperature of the light emitting section.

Therefore, it is possible to easily calculate the adjustment value for controlling the temperature of the light emitting section based on the temperature characteristic information.

The media detection apparatus (detection apparatus 20) according to the present embodiment includes the storage section 27 that stores temperature characteristic information.

Therefore, the temperature characteristic information can be easily acquired from the storage section 27.

In the media detection apparatus (detection apparatus 20) according to the present embodiment, the temperature controller (detection controller 21) controls the temperature of the light emitting section (second light emitting section 232) before the detection of the moisture information.

Therefore, the moisture information can be more accurately detected by detection of the moisture information in a state where the wavelength of the light emitted from the light emitting section is the predetermined wavelength (the target wavelength).

In the media detection apparatus (the detection apparatus 20) according to the present embodiment, when the moisture information is not detected, the temperature controller (the detection controller 21) controls the temperature of the light emitting section by supplying a current to the light emitting element of the light emitting section (the second light emitting section 232).

Therefore, the temperature of the light emitting section can be easily controlled by applying a current to the light emitting element of the light emitting section.

In the media detection apparatus (detection apparatus 20) according to the present embodiment, when the moisture information is not detected, the temperature controller (detection controller 21) controls the temperature of the light emitting section by changing the duty ratio of the current to be supplied to the light emitting element of the light emitting section (second light emitting section 232).

Therefore, the temperature of the light emitting section can be easily controlled by changing the duty ratio of the current flowing through the light emitting element of the light emitting section.

In the media detection apparatus (detection apparatus 20) according to the present embodiment, the temperature controller (detection controller 21) controls the temperature of the light emitting section during the detection of the moisture information, based on the measurement result of the temperature sensor 237 disposed in the vicinity of the light emitting section (second light emitting section 232) or the measurement result of the environmental temperature.

Therefore, it is possible to appropriately control the temperature of the light emitting section based on the measurement result of the temperature sensor 237 disposed in the vicinity of the light emitting section or the measurement result of the environmental temperature.

The image forming system 100 according to the present embodiment includes a media detection apparatus (detection apparatus 20) and an image forming section 38 capable of forming an image on a sheet.

Thus, image formation corresponding to the moisture information accurately detected by the detection apparatus 20 can be performed.

The description in the above embodiment is an example of the media detection apparatus, the image forming system, and the program according to the present disclosure and is not limited thereto. The detailed configuration and detailed operation of each part constituting the apparatus can also be appropriately changed without departing from the spirit of the present disclosure.

For example, although the case where the detection controller 21 is the temperature controller has been described in the above embodiment, it is not limited thereto. The controller 31 of the image forming apparatus 30 may function as the temperature controller.

In the above-described embodiment, the application of the media detection apparatus to the electrophotographic image forming apparatus 30 in which the printing method is the electrophotographic method is exemplified, but the invention is not limited thereto, and the media detection apparatus can be applied to an image forming apparatus of an inkjet method or an image forming apparatus of another printing method.

Although embodiments of the present invention have been described and illustrated in detail, the disclosed embodiments are made for purposes of illustration and example only and not limitation. The scope of the present invention should be interpreted by terms of the appended claims.

What is claimed is:

1. A media detection apparatus for detecting moisture information corresponding to a moisture amount or a moisture percentage of a sheet, the media detection apparatus comprising:
a moisture sensor including a light emitter that emits light and a light receiver that receives the light reflected off the sheet or transmitted through the sheet; and
a hardware processor that controls a temperature of the light emitter such that a wavelength of the light emitted from the light emitter becomes a predetermined wavelength.

2. The media detection apparatus according to claim 1, wherein the hardware processor controls the temperature of the light emitter during detection of the moisture information based on a measurement result by a temperature sensor disposed near the light emitter.

3. The media detection apparatus according to claim 1, further comprising at least one of a heater that heats the light emitter and a cooler that cools the light emitter.

4. The media detection apparatus according to claim 3, wherein the hardware processor heats the light emitter by passing a current through a resistor included in the heater, the resistor being disposed near the light emitter.

5. The media detection apparatus according to claim 3, wherein the hardware processor cools the light emitter with at least one of a fan motor and a Peltier element included in the cooler.

6. The media detection apparatus according to claim 1, wherein the light emitter includes a light emitting diode or a laser diode.

7. The media detection apparatus according to claim 1, wherein the hardware processor controls the temperature of the light emitter based on temperature characteristic information indicating a correspondence relationship between the wavelength of the light and the temperature of the light emitter for each light emitting element of the light emitter.

8. The media detection apparatus according to claim 7, further comprising a storage that stores the temperature characteristic information.

9. The media detection apparatus according to claim 1, wherein the hardware processor controls the temperature of the light emitter before detection of the moisture information.

10. The media detection apparatus according to claim 9, wherein the hardware processor controls the temperature of the light emitter by supplying a current to a light emitting element of the light emitter when the moisture information is not detected.

11. The media detection apparatus according to claim 9, wherein the hardware processor controls the temperature of the light emitter by changing a duty ratio of a current to be supplied to a light emitting element of the light emitter when the moisture information is not detected.

12. The media detection apparatus according to claim 9, wherein the hardware processor controls the temperature of the light emitter during detection of the moisture information based on a measurement result by a temperature sensor disposed near the light emitter or a measurement result of an environmental temperature.

13. An image forming system comprising:
the media detection apparatus according to claim 1; and
an image former capable of forming an image on the sheet.

14. A non-transitory recording medium storing a computer readable program for a computer of a media detection apparatus for detecting moisture information corresponding to a moisture amount or a moisture percentage of a sheet, the media detection apparatus including a moisture sensor including: a light emitter that emits light; and a light receiver that receives the light reflected off the sheet or the light transmitted through the sheet, and the program causing the computer to perform
controlling a temperature of the light emitter such that a wavelength of the light emitted from the light emitter becomes a predetermined wavelength.
